(19) United States
(12) Patent Application Publication
(10) Pub. No.: US 2007/0088994 A1
(43) Pub. Date: Apr. 19, 2007

(54) ELECTRONIC DEVICE TESTING SYSTEM, METHOD, AND CONTROL DEVICE UTILIZED IN SAME

(75) Inventors: YI LO, Tu-Cheng (TW); YI-TSAI CHEN, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/308,055

(22) Filed: Mar. 4, 2006

(30) Foreign Application Priority Data
Sep. 30, 2005 (TW) 94134302

(51) Int. Cl. G01R 31/28

(52) U.S. Cl. 714/724

(57) ABSTRACT

An exemplary testing system (10) for testing an electronic device (300) under test includes a testing device (100) and a control device (200). The electronic device under test includes a transmitting element (320) and a keyboard (340). The testing device generates and sends instructions. The control device is connected to the testing device, and is used for receiving the instructions sent by the testing device, decoding the instructions, and acting according to the decoded instructions. The control device is also for connecting to the transmitting element to retrieve data from the transmitting element, and for connecting to the keyboard to control the keyboard. A control device for utilization in the testing system and a testing method are also provided.

### FIELD OF THE INVENTION

The present invention relates to electronic device testing systems, and particularly to a testing system, a testing method, and a control device utilized in the testing system.

### DESCRIPTION OF RELATED ART

Interactive electronic devices such as mobile phones and personal digital assistants have major components that include motherboards, display modules, and keyboards. Newly manufactured interactive electronic devices must be inspected and tested for quality before leaving the factory. Usually, interactive electronic devices are inspected and tested by a testing device such as a computer. The testing device sends instructions via a console port to the interactive electronic devices under test. The interactive electronic devices decode the received instructions, act accordingly, and send corresponding data to the testing device. The testing device determines whether the interactive electronic devices can operate normally according to the data.

Because the interactive electronic devices need to decode the received instructions, the interactive electronic devices need to have decoding software pre-installed therein. However, the decoding software is not required for normal operation of the interactive electronic devices by end users. Therefore, software loadings and the costs of the interactive electronic devices are increased.

In addition, each interactive electronic device has a display module, whose displaying capability must also be inspected and tested. That is, the testing device needs to capture image data from the display module. If an interactive electronic device under test crashes, the testing device cannot capture image data from the display module.

### SUMMARY OF INVENTION

An exemplary embodiment of the present invention provides a testing system. The testing system is used for testing an electronic device, and includes a testing device and a control device. The electronic device includes a transmitting element and a keyboard. The testing device is used for generating and sending instructions. The control device is connected to the testing device, and is used for receiving the instructions sent by the testing device, decoding the instructions, acting according to the decoded instructions. The control device is also for connecting to the transmitting element to retrieve data from the transmitting element, and for connecting to the keyboard to control the keyboard.

Another exemplary embodiment of the present invention provides a control device for utilization in a testing system. The testing system is used for testing an electronic device having a transmitting element and a keyboard, and includes a testing device for generating and sending instructions. The control device includes a controller, a buffer, and a relay circuit. The controller is connected to the testing device, and is used for receiving the instructions sent by the testing device, decoding the instructions, acting according to decoded instructions. The controller is also for connecting to the transmitting element of the electronic device to retrieve data from the transmitting element. The buffer is connected to the controller, and is used for temporarily storing the retrieved data. The relay circuit is connected to the controller, and is for connecting to the keyboard of the electronic device. The relay circuit is operated according to the decoded instructions of the controller, thereby controlling the keyboard.

A further exemplary embodiment of the present invention provides a method for testing an electronic device. The testing method includes: generating instructions by a testing device, and sending the instructions to a control device; decoding the instructions after the control device receives the instructions; reading the decoded instructions and acting according to the decoded instructions by the control device; and retrieving data, and sending the data to the testing device.

Because the control device can decode instructions, there is no need for the electronic device to have decoding software pre-installed therein. Thus, the software loading and the cost of the electronic device are reduced. In addition, if the electronic device crashes, data of the electronic device can still be collected.

Furthermore, because the control device is connected to the transmitting element of the electronic device, when the testing device captures image data, the electronic device simultaneously sends the image data to the display module and the control device. The control device then sends the image data to the testing device. Therefore, the electronic device and the testing device show images almost simultaneously. Thus, the testing time is shortened, and the testing efficiency is improved.

Other advantages and novel features will become more apparent from the following detailed description of preferred embodiments when taken in conjunction with the accompanying drawings, in which:

### BRIEF DESCRIPTION OF DRAWINGS

FIG. 1 is a block diagram of a testing system of an exemplary embodiment of the present invention, together with an electronic device under test;

FIG. 2 is a block diagram showing more details of the parts shown in FIG. 1;

FIG. 3 is a flowchart of a testing method of another exemplary embodiment of the present invention; and

FIG. 4 is a flowchart of a testing method of still another exemplary embodiment of the present invention.

### DETAILED DESCRIPTION

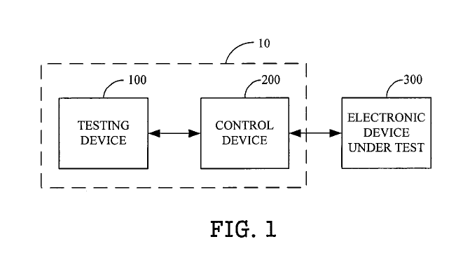

FIG. 1 is a block diagram of a testing system 10 of an exemplary embodiment of the present invention, together with an electronic device 300 under test. In the exemplary embodiment, the testing system 10 includes a testing device 100 and a control device 200. The testing device 100 is used for generating and sending instructions. In the exemplary embodiment, the testing device 100 may be a computer, and instructions generated by the testing device 100 include an image collecting command and a key command. The control device 200 is connected to the testing device 100, and is for connecting to the electronic device 300 under test. The control device 200 is used for receiving instructions sent by the testing device 100, decoding the received instructions, and acting according to the decoded instructions. The electronic device 300 under test is an interactive electronic device such as a mobile phone, a personal digital assistant, and the like.

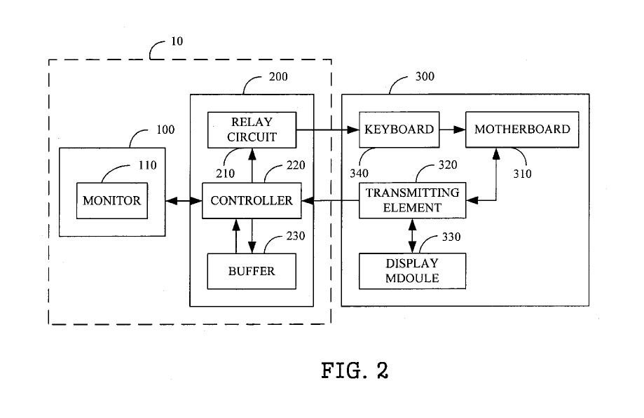

FIG. 2 is a block diagram showing more details of the parts shown in FIG. 1. The electronic device 300 under test includes a motherboard 310, a display module 330, a transmitting element 320, and a keyboard 340. The transmitting element 320 can be a transmitting line. The keyboard 340 is connected to the motherboard 310 for actuating the motherboard 310 to send data. The motherboard 310 sends data according to inputted data of the keyboard 340. Data sent by the motherboard 310 includes image data. The display module 330 is used for displaying the data sent by the motherboard 310. The transmitting element 320 is connected to the motherboard 310 and the display module 330, and is used for transmitting the data sent by the motherboard 310 to the display module 330. The motherboard 310 also can automatically send data to the display module 330 via the transmitting element 320. In the exemplary embodiment, the testing device 100 includes a monitor 110 for displaying image data.

The control device 200 includes a relay circuit 210, a controller 220, and a buffer 230. The controller 220 is connected to the testing device 100, and is for connecting to the transmitting element 320 of the electronic device 300 under test. The controller 220 is used for receiving the instructions sent by the testing device 100, decoding the received instructions, acting according to the decoded instructions, and retrieving the data sent by the motherboard 310 from the transmitting element 320.

The relay circuit 210 is connected to the controller 220, and is for connecting to the keyboard 340. The relay circuit 210 is operated corresponding to the decoded instructions of the controller 220, and thereby controls the keyboard 340. The relay circuit 210 includes multiple relays respectively for connecting to keys of the keyboard 340. The relays are used for automatically actuating corresponding keys of the keyboard 340 according to the decoded instructions of the controller 220. In the exemplary embodiment, the relay circuit 210 includes thirty-two relays.

The buffer 230 is connected to the controller 220, and is used for temporarily storing data retrieved by the controller 220 from the transmitting element 320. In the exemplary embodiment, the buffer 230 is a first-in first-out buffer. The controller 220 is also used for retrieving data from the buffer 230, and sending the data retrieved from the buffer 230 to the testing device 100.

When the testing device 100 sends instructions to the control device 200, the controller 220 of the control device 200 decodes the received instructions, and reads the decoded instructions. Thereby, the controller 220 determines whether the instructions are image collecting commands or key commands. When the instructions are key commands, the controller 220 controls action of the relay circuit 210, thereby controlling the keyboard 340 to automatically actuate the motherboard 310 to send data to the display module 330 via the transmitting element 320. Simultaneously, the controller 220 retrieves the data sent by the motherboard 310 from the transmitting element 320, and stores the data in the buffer 230. In the exemplary embodiment, the data retrieved by the controller 220 from the transmitting element 320 includes image data.

When the instructions are image collecting commands, the controller 220 retrieves data in the buffer 230, and sends the data retrieved from the buffer 230 to the testing device 100.

When a current data storage of the buffer 230 reaches a certain threshold level, the controller 220 notifies the testing device 100 to retrieve all data in the buffer 230. The threshold level is predetermined based on two criteria: no loss of data should occur up to and including the threshold level, and no delay should occur in displaying the data up to and including the threshold level. In the exemplary embodiment, the threshold level is that the current data storage is half of the entire capacity of the buffer 230.

When the testing device 100 has not received data sent by the controller 220 for a predetermined period of time, the testing device 100 generates an image collecting command, and sends the image collecting command to the controller 220. After receiving the image collecting command, the controller 220 decodes the command, and determines that the command is an image collecting command. Then the controller 220 retrieves data in the buffer 230 according to the image collecting command, and sends the retrieved data to the testing device 100. The predetermined period is based on the criterion that no delay should occur between displaying of image data on the monitor 110 of the testing device 100 and displaying of the image data on the display module 330 of the electronic device 300 under test. In the exemplary embodiment, the predetermined period is 25 milliseconds.

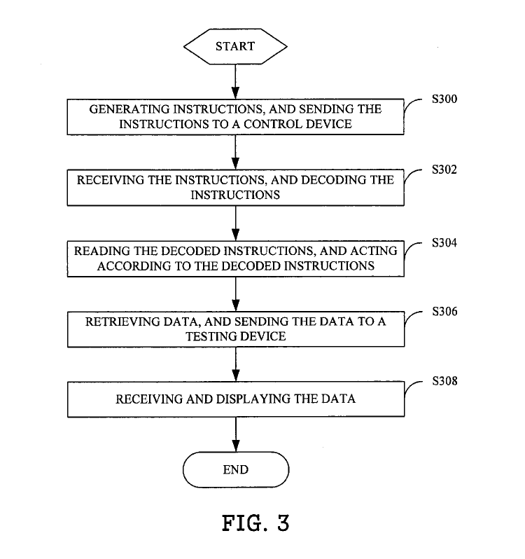

FIG. 3 is a flowchart of a testing method of another exemplary embodiment of the present invention. In step S300, the testing device 100 generates instructions, and sends the instructions to the control device 200. In step S302, the controller 220 of the control device 200 receives the instructions, and decodes the instructions. In step S304, the controller 220 reads the decoded instructions, and acts according to the decoded instructions. In step S306, the controller 220 retrieves data, and sends the data to the testing device 100. In step S308, the testing device 100 receives and displays the data. In the exemplary embodiment, the testing device 100 firstly decodes the data, and then displays the decoded data on the monitor 110.

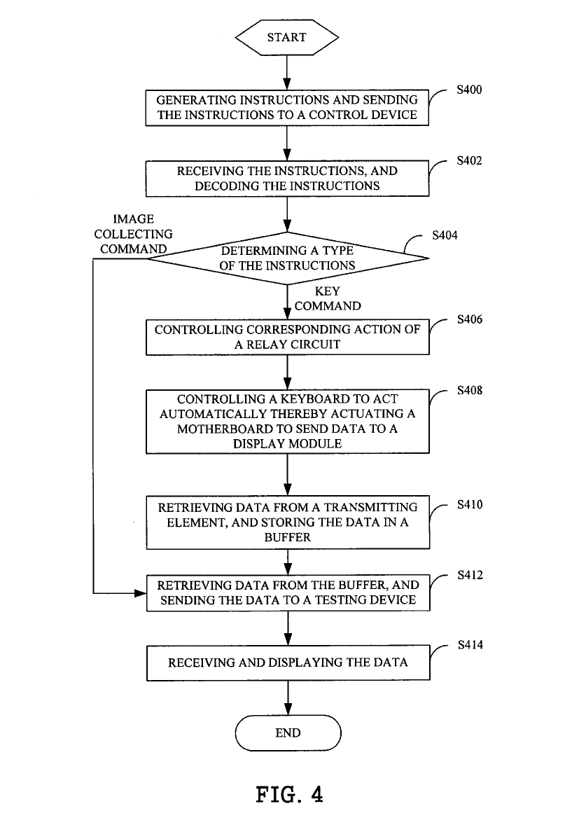

FIG. 4 is a flowchart of a testing method of a further exemplary embodiment of the present invention. In step S400, the testing device 100 generates instructions, and sends the instructions to the control device 200. In the exemplary embodiment, the instructions includes image collecting commands and key commands. In step S402, the controller 220 receives the instructions, and decodes the instructions. In step S404, the controller 220 determines a type of the instructions.

If the controller 220 determines that the instructions are key commands, in step S406, the controller 220 controls corresponding action of the relay circuit 210. In step S408, the relay circuit 210 controls the keyboard 340 of the electronic device 300 under test to act automatically, thereby actuating the motherboard 310 to send data to the display module 330 via the transmitting element 320. In step S410, the controller 220 retrieves the data sent by the motherboard 310 from the transmitting element 320, and stores the retrieved data in the buffer 230.

In step S412, the controller 220 retrieves data from the buffer 230, and sends the retrieved data to the testing device 100. In the exemplary embodiment, when a current data storage of the buffer 230 reaches a certain threshold level, the controller 220 notifies the testing device 100 to retrieve all data in the buffer 230. The threshold level is predetermined based on two criteria: no loss of data should occur up to and including the threshold level, and no delay should occur in displaying the data up to and including the threshold level. In the exemplary embodiment, the threshold level is that the current data storage is half of the entire capacity of the buffer 230.

In step S414, the testing device 100 receives and displays data sent by the controller 220. In the exemplary embodiment, the testing device 100 firstly decodes the data, and then displays the decoded data on the monitor 110.

If in step S404 the controller 220 determines that the instructions are image collecting commands, the process advances directly to step S412 described above. That is, the controller 220 retrieves data from the buffer 230, and sends the retrieved data to the testing device 100. The process then advances to step S414 described above.

Because the control device 200 can decode instructions, there is no need for the electronic device 300 under test to have decoding software pre-installed therein. Thus, the software loading and the cost of the electronic device 300 under test are reduced. In addition, if the electronic device 300 under test crashes, data of the electronic device 300 under test can still be collected.

Furthermore, because the control device 200 is connected to the transmitting element 320 of the electronic device 300 under test, when the testing device 100 captures image data, the electronic device 300 under test simultaneously sends the image data to the display module 330 and the control device 200. The control device 200 then sends the image data to the testing device 100. Therefore, the electronic device 300 under test and the testing device 100 show images almost at the same time. Thus, the testing time is shortened, and the testing efficiency is improved.

While various embodiments have been described above, it should be understood that they have been presented by way of example only and not by way of limitation. Thus the breadth and scope of the present invention should not be limited by the above-described exemplary embodiments, but should be defined only in accordance with the following claims and their equivalents.

What is claimed is:

1. A testing system, for testing an electronic device comprising a transmitting element and a keyboard, the testing system comprising:
a testing device for generating and sending instructions; and
a control device, connected to the testing device, for receiving the instructions sent by the testing device, decoding the received instructions, and acting according to the decoded instructions, for connecting to the transmitting element to retrieve data from the transmitting element, and for connecting to the keyboard to control the keyboard.

2. The testing system as claimed in claim 1, wherein the control device comprises:
a controller, connected to the testing device, for receiving the instructions sent by the testing device, decoding the received instructions, acting according to the decoded instructions, and for connecting to the transmitting element to retrieve data from the transmitting element;
a buffer, connected to the controller, for temporarily storing the retrieved data; and
a relay circuit, connected to the controller, for connecting to the keyboard, and for operating according to the decoded instructions of the controller and thereby controlling the keyboard.

3. The testing system as claimed in claim 2, wherein the buffer comprises a first-in first-out buffer.

4. The testing system as claimed in claim 2, wherein the controller is also for retrieving data from the buffer and sending the data retrieved from the buffer to the testing device.

5. The testing system as claimed in claim 1, wherein the instructions generated by the testing device comprise an image collecting command and a key command.

6. The testing system as claimed in claim 1, wherein the retrieved data comprise image data.

7. A control device for utilization in a testing system that is used for testing an electronic device, the electronic device comprising a transmitting element and a keyboard, the testing system comprising a testing device for generating and sending instructions, the control device comprising:
a controller for connecting to the testing device, receiving instructions sent by the testing device, decoding the received instructions, and acting according to the decoded instructions, and for connecting to the transmitting element to retrieve data from the transmitting element;
a buffer connected to the controller, for temporarily storing the retrieved data; and
a relay circuit connected to the controller, for connecting to the keyboard, and operating according to the decoded instructions of the controller and thereby controlling the keyboard.

8. The control device as claimed in claim 7, wherein the buffer comprises a first-in first-out buffer.

9. The control device as claimed in claim 7, wherein the controller is also used for retrieving data from the buffer and sending the data retrieved from the buffer to the testing device.

10. The control device as claimed in claim 7, wherein the instructions received by the control device comprise an image collecting command and a key command.

11. The control device as claimed in claim 7, wherein the retrieved data comprise image data.

12. A method for testing an electronic device, comprising the steps of:
generating instructions by a testing device, and sending the instructions to a control device;
decoding the instructions after the control device receives the instructions;
reading the decoded instructions and acting according to the decoded instructions by the control device; and
retrieving data, and sending the data to the testing device.

13. The method as claimed in claim 12, wherein the data comprise image data.

14. The method as claimed in claim 12, further comprising receiving and displaying the data.

15. The method as claimed in claim 12, wherein the step of reading the decoded instructions and acting according to the decoded instructions comprises:
controlling action of a relay circuit when the instructions comprise a key command;
controlling a keyboard of the electronic device to act automatically, thereby actuating a motherboard of the electronic device to send data to a display module of the electronic device via a transmitting element of the electronic device; and
retrieving data from the transmitting element of the electronic device, and storing the data in a buffer of the control device.

16. The method as claimed in claim 12, wherein the step of reading decoded instructions and acting according to the decoded instructions comprises retrieving data from a buffer of the control device when the instructions comprise an image collecting command.
